(19) United States
(12) Patent Application Publication
(10) Pub. No.: US 2006/0279436 A1
(43) Pub. Date: Dec. 14, 2006

(54) Digital elevation model data structure for geospatial analysis

(76) Inventors: Russell Andrew Ambroziak, Locust Grove, VA (US); Jeffrey Russell Ambroziak, Guilford, CT (US); Brian Michael Ambroziak, Knoxville, TN (US)

Correspondence Address: Jeffrey R. Ambroziak, 563 Lake Drive, Guilford, CT, 06437, US

(21) Appl. No.: 11/390,007

(22) Filed: Mar. 27, 2006

Related U.S. Application Data
(60) Provisional application No. 60/665,493, filed on Mar. 25, 2005.

(51) Int. Cl. H03M 7/00

(52) U.S. Cl. 341/50

(57) ABSTRACT

A data structure stored on a computer readable storage media comprises a plurality of layers each comprising a data array and a corresponding normal vector array, and a plurality of layer structures each comprising information related to a corresponding one of the plurality of layers.

### CROSS-REFERENCE TO RELATED APPLICATIONS

This application claims the benefit of U.S. Provisional Application No. 60/665,493 filed Mar. 25, 2005 which is hereby incorporated by reference.

### TECHNICAL FIELD

This invention relates generally to a digital elevation model. More particularly, the invention relates to a structure for enabling the storage and access of geo-spatial data.

### BACKGROUND

Digital elevation models (DEM) are typically comprised of rectangular arrays of a number of rows and columns wherein there is stored at each row and column a value corresponding to an elevation. The rows and columns of a DEM correspond to intersecting lines of latitude and longitude on a spherical surface, typically the earth, with the stored elevation values representing the height of the earth at the given latitude and longitude. When the data elements comprising a DEM are plotted according to their latitude and longitude at their respective elevations and connected to adjoining data elements by straight lines, the resultant visualization of the DEM appears as a wireframe rendering of a surface. With reference to FIG. 1A, there is illustrated a typical wireframe visualization of a DEM 11 as viewed from directly above. It is evident that DEM 11 is comprised of rows and columns. It is further evident that at the intersection of each row and column there exists a node 31. As previously stated, node 31 has a value equal to an elevation. As can be seen with reference to FIG. 1b, illustrating a perspective view of DEM 11, each node 31 has a row attribute 33, a column attribute 35, and an elevation attribute 37.

Most data formats used to represent DEMs store the DEMs in a projected format. That is to say, the latitude and longitude of each elevation point is projected using a map projection to form an image. The spatial characteristics of the elevation values stored in the resulting projected image are then overlayed on the data array comprising the DEM 11. While DEMs 11 constructed in this manner may be readily accessed and displayed in a visually pleasing manner, latitude and longitude information is lost in the process. As a result, it is neither easy nor necessarily possible to derive the latitudes and longitude of individual points of elevation stored in DEMs 11 common to the art. While some DEM formats provide projection information from which one might theoretically derive such latitude and longitude information, many do not. As a result, it is oftentimes not possible to combine the data contained in more than one DEM 11 when any one DEM 11 was projected in a manner different from that of any other DEM and where at least one such DEM does not include projection information. Even in cases where such projection information is present for all DEMs 11 sought to be combined, it is computationally disadvantageous to attempt to do so.

DEMs 11 are typically used to model the surface terrain values associated with and corresponding to an area of the earth or other spherical body. In addition, DEMs 11 are often projected by themselves and in conjunction with other image data to create pictorial representations of geospatial data. As a result, DEMs 11 are commonly manipulated to compute additional information for use in displaying geospatial data. For example, it is possible using the information in a DEM 11 to compute shadows as they would appear were sunlight to be directed at the DEM 11 from a uniform direction. These renderings of DEMs 11 require, in addition to the elevation information recorded at each and every node 31, information describing a vector normal to the surface of the DEM 11. Because computing even a single normal vector requires the derivation of at least two, preferably four, and possibly many more vectors from the DEM 11, as well as a number of computations, the task of computing the normal vectors covering any appreciable expanse of a DEM 11 can be daunting.

In addition, the attributes of a typical DEM render it ill suited to the demands of graphic representation. DEMs 11 as well as geospatial images pose special problems arising from the manner in which they are typically viewed. If one intends to use the DEM 11 to display and model the surface characteristics of the United States as a whole and to display it upon a computer screen wherein the screen is comprised of an array of pixels typically 800 by 600 pixels, it may make sense from a design standpoint to construct a DEM such that the average longitudinal and latitudinal differences between rows and columns is equal to approximately 1 kilometer.

While such a resolution may be optimal for viewing the United States as a whole, it is of considerably less benefit if one were to zoom into an area of the DEM 11. If, for example, one were to zoom in on an area the size of a county, or a single lot within the county, there would be insufficient detail in the DEM 11 at a resolution of approximately 1 kilometer to accurately describe the area being viewed. However, if the DEM 11 to be constructed was chosen to have an average resolution of approximately 2 meters, the resulting DEM 11 of the entire country could be hundreds of gigabytes in size and therefore too large to be manipulated on a standard personal computer. Unfortunately, when viewing geospatial data such as DEMs 11 or geospatial images, such as georeferenced maps or satellite images, it is common to zoom out to obtain a view of a wide geospatial expanse as well as to zoom in to a relatively small area of interest.

This fact creates several problems. The first problem, previously noted, results from the fact that constructing a DEM 11 of sufficient resolution to provide for the analysis and visualization of small areas by necessity results in a DEM of such large size when viewed in its entirety that it may outpace the capabilities of the computer upon which it is being viewed and manipulated. In addition, as DEMs increase in size, operations performed upon the data contained therein likewise increase in number and in the amount of time required to complete the computations. Therefore, it is often necessary when using traditional DEMs 11 to engage in a tradeoff between the resolution that may be achieved through viewing and manipulating the DEM 11 and a speed with which such manipulations may be accomplished.

Second, as noted, when visualizing DEMs 11 it is often advantageous to compute vectors normal to the surface represented by the DEM 11 at each node. Because the direction vector of the normal vector of each node 31 in a DEM 11 is tied to the elevation data itself, it may be computed from the DEM 11. However, the continual re-computation of the normal vectors from a DEM is redundant and wasteful. As a result, the manipulation of typical DEMs suffer from drawbacks related to the large size of a DEM required in order to view sections of the DEM at a high resolution as well as large expanses of the DEM at small resolutions, and in all cases require a daunting amount of computation to continually recompute or to compute once and store direction information related to normal vectors for each node 31 of the DEM 11.

### SUMMARY OF THE PREFERRED EMBODIMENTS

The foregoing and other problems are overcome, and other advantages are realized, in accordance with the presently preferred embodiments of these teachings.

In accordance with an embodiment of the invention, a data structure stored on a computer readable storage media comprises a plurality of layers each comprising a data array and a corresponding normal vector array, and a plurality of layer structures each comprising information related to a corresponding one of the plurality of layers.

In accordance with an embodiment of the invention, a signal bearing medium tangibly embodies a program of machine-readable instructions executable by a digital processing apparatus to perform operations comprising retrieving data from a data structure comprising a plurality of layers each comprising a data array and a corresponding normal vector array, and a plurality of layer structures each comprising information related to a corresponding one of the plurality of layers, and displaying the retrieved data.

### BRIEF DESCRIPTION OF THE DRAWINGS

The foregoing and other aspects of these teachings are made more evident in the following Detailed Description of the Preferred Embodiments, when read in conjunction with the attached Drawing Figures, wherein:

FIG. 1a is an illustration of a digital elevation model known in the art.

FIG. 1b is a perspective illustration of a digital elevation model known in the art.

FIG. 2 is an illustration of an exemplary embodiment of a DEM data structure of the invention.

FIG. 3 is a diagram of an exemplary embodiment of an apparatus for utilizing a DEM data structure of the invention.

FIG. 4 is a diagram illustrating an exemplary mask embodiment of a mask of the invention.

FIG. 5 is a diagram illustrating an exemplary embodiment of the invention y which a normal vector is computed.

FIG. 6 is a diagram of an exemplary embodiment of a data element of the invention.

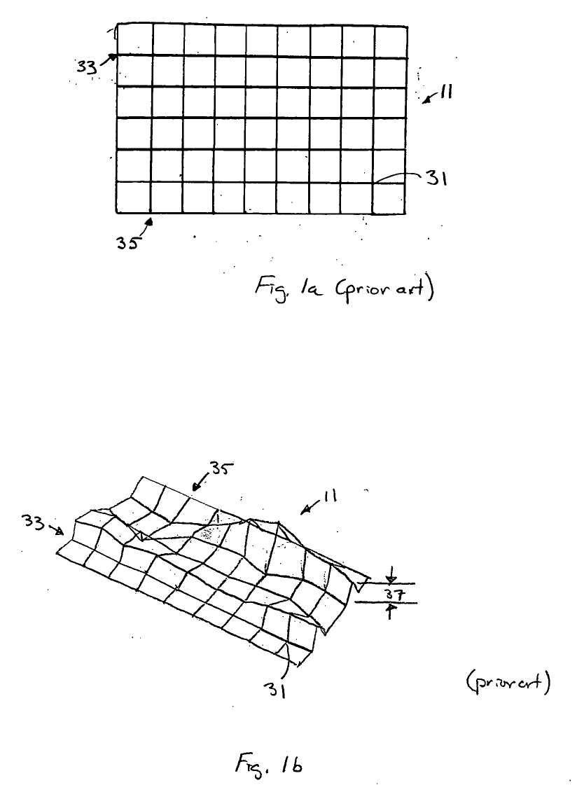

### DETAILED DESCRIPTION OF THE PREFERRED EMBODIMENTS

In exemplary embodiments of the invention, there is taught a DEM data structure comprising data that is stored in and is accessible from a computer readable medium. In an exemplary embodiment, the DEM data structure 21 stores the data in an unprojected format. Specifically, elevation points stored in a DEM structure 21 are associated with accessible, corresponding latitude and longitude attributes. The DEM data structure 21 provides the capability to store large amounts of high resolution elevation data while facilitating the rapid acquisition and display of the DEM data structure's 21 data or any subsection of the data regardless of the resolution at which it is displayed. In another exemplary embodiment of the invention, the DEM data structure 21 facilitates the rapid computation of normal vectors to the surface represented by the DEM data structure 21 at any or all nodes comprising the DEM data structure 21.

As used herein, “data element” refers to the value of a data array defined by a unique row and column designation. As described herein, a DEM data structure 21 stores geospatial data having, at least, an attribute corresponding to elevation. In an exemplary embodiment of the invention, the elevation attribute is replaced with an attribute having a magnitude other than elevation, such as, for example, the average income or the percentage of people between the ages of five and twelve associated with a longitude and latitude. In such an instance, the general structure of the DEM data structure 21 is unchanged and is referred to as a digital data model (DDM) structure.

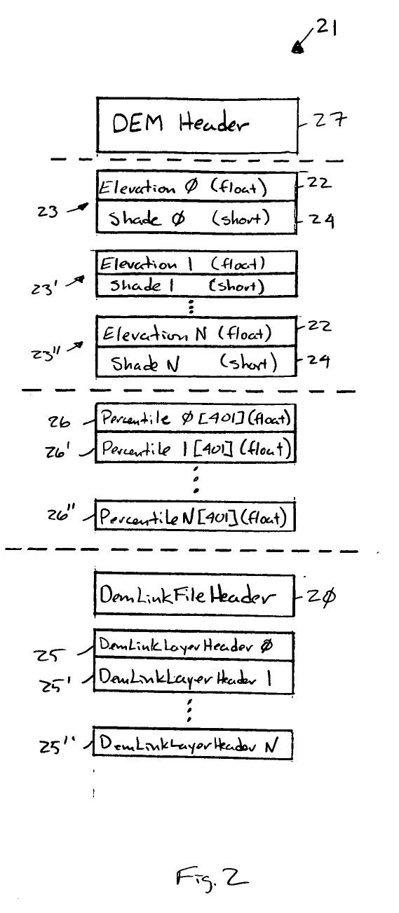

With reference to FIG. 2, there is illustrated an exemplary embodiment of the DEM data structure 21 of the invention. DEM structure 21 consists of a header structure 27, one or more DEM layers 23, 23′, 23″ and one or more layer structures 25, 25′, 25″ wherein each DEM layer 23 corresponds to a unique layer structure 25. Each DEM layer 23 is comprised of a DEM data array 22 and a normal vector array 24. As described herein, DEM structure 21 is the logical specification of the data format of a structure which contains the data comprising a DEM of the invention. Therefore, in practice, the data comprising a DEM is preferably stored in contiguous bytes on a medium capable of storing binary data such that the layout of the bytes of information comprising the DEM correspond to DEM structure 21.

DEM header structure 27 is comprised of one or more data fields, each data field comprised of information descriptive of a DEM 11. Such data fields may include, but are not limited to, information related to the latitude and longitude of the area covered by the DEM 11, the latitude and longitude of the upper left most data element, a pointer to the first layer structure 25, the number of data elements per degree of longitude, the number of data elements per degree of latitude, and the number of layer structures 25 included in the DEM data structure 21. In the instance of a DDM data structure 21, header structure 27 may additionally include the units of measurement of the data elements. In an exemplary embodiment of the invention, a layer structure header 20 is included that contains information about the layer structures 25.

One or more DEM layers 23 follow DEM header 27. Each DEM layer 23 is comprised of one each DEM data array 22 and normal vector array 24. Both DEM data array 22 and normal vector array 24 consist of data arrays wherein each array is comprised of rows and columns. Preferably, both the DEM data array 22 and the normal vector array 24 joined to form a single DEM layer 23 are formed such that each has the same number of rows and the same number of columns as the other. In the instance that a DEM data structure 21 is comprised of more than one DEM layer 23, each successive DEM layer 23 differs in size from each other DEM layer 23. Preferably successive DEM layers 23 are smaller than each preceding DEM layer 23. Most preferably, each succeeding DEM layer 23 represents a sampled instance of the preceding DEM layer 23 sampled at a uniform rate. In such an instance, each succeeding DEM layer 23 has a size approximately equal to the size in bytes of the preceding DEM layer 23 divided by the square of the sample rate. For example, if succeeding DEM layers 23 are formed by sampling the preceding DEM layer by a factor of two, the resultant DEM layer 23 is approximately one fourth the size of the DEM layer 23 from which it was computed. Likewise, sampling by a factor of three will result in DEM layers 23 that are approximately one ninth the size of the DEM layer 23 from which each is computed. In an exemplary embodiment, DEM layers 23 are sampled with a sample rate of two as is described more fully below.

Each DEM data array 22 is comprised of an array of elevation values. As such, the DEM data array 22 is comprised of a number of rows and columns. In an exemplary embodiment, these rows and columns correspond to lines of equal latitude and longitude, respectively. While the number of data elements per degree of longitude is constant between data elements, as are the number of data elements per degree of latitude, the two numbers need not be the same and are, as noted, stored in the header structure 27. Each coupled row and column may be translated into a latitude and longitude using the information contained in the layer structure 25 corresponding to each DEM layer 23. Therefore, the elevation data stored at each row and column designation of a DEM data array 22 can be mapped to a latitude and longitude on a spherical surface and used to model the topography of the surface.

As noted, each DEM data array 22 is coupled with a corresponding normal vector array 24 to form a DEM layer 23. Whereas each data element of the DEM data array 22 contains a value corresponding to an elevation, normal vector array 24 is comprised of data elements in which is stored three dimensional vector information. Specifically, the data elements of normal vector array 24 contain the x, y, and z vector information defining a vector normal to the surface defined in the corresponding DEM data array 22 located at the same row and column. The x, y, and z vectors correspond to the longitude, latitude, and elevation respectively of the surface modeled by the DEM data structure 21. For example, DEM array [12][10] (read as the data element of DEM data array 22 located at row 12 and column 10) may contain an elevation of 230 meters. If the data element at DEM array [12][10] represents a flat portion of the DEM, then a unit vector normal to the data element would be [0,0,1]. As used herein, “unit vector” refers to a vector of unit length. Therefore normal vector array [12][10] (read as the data element of normal vector array 24 located at row “12” and column “10”) will contain information defining the vector [0,0,1]. As can be seen, DEM data array 22 and normal vector array 24 are therefore preferably comprised of the same number of rows and columns. In this manner, it is possible to retrieve both the elevation and direction data of a point in the DEM by accessing the appropriate data element in the DEM data array 22 and the corresponding data element in normal vector array 24. While both DEM data array 22 and normal vector array 24 preferably have the same number of rows and columns, the number of bytes required to store both arrays 22, 24 may differ. In an exemplary embodiment described more fully below, DEM data array 22 is comprised of an array of floating point numbers, each typically four bytes in length while the normal vector array is comprised of an array of short integers typically two bytes in length.

Each DEM layer 23 has a unique corresponding layer structure 25. Each layer structure 25 contains information describing a corresponding DEM layer 23. Layer structures 25 may contain, but is not limited to, information regarding the degree separation of the rows and columns in the corresponding DEM layer 23, the number of rows and columns, a scaling factor, pointers to the corresponding DEM data array 22 and normal vector array 24, and information for converting row and column designations to latitude and longitude.

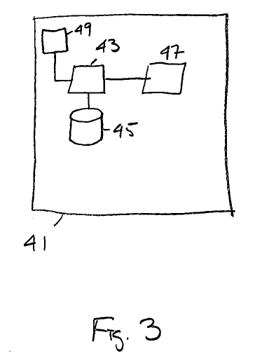

With reference to FIG. 3, there is illustrated an exemplary embodiment of a computing device 41 for utilizing the DEM data structure 21 of the invention. Computing device 41 is any device capable of accessing and processing digital data including, but not limited to, personal computers, personal digital assistants, portable computers, mainframe computers and the like. Computing device includes a processor 43 coupled to a computer readable storage medium such as memory 45. Memory 45 can store a DEM data structure 21 for use by the processor 43. Processor 43 can also be coupled to a user input device 47 including, but not limited to, a keyboard or a mouse for instructing the processor to manipulate a DEM data structure 21. Processor 43 can be coupled to a display device, such as a computer monitor, for displaying the contents of a DEM data structure 21.

In an exemplary embodiment, in practice, processor 43 executing an application or executable can open a file containing DEM data formatted according to the DEM structure 21 of the invention. Upon accessing the DEM data structure 21, one can extract the number of layer structures 25 from header structure 27 as well as the location of the first byte of the first layer structure 25. Space can then be allocated in memory 45 sufficient to hold all of the layer structure information 25, the data structure 25 data can be accessed, and data can be copied into the allocated space. Subsequently, when the application requires DEM information, it need only look at the data structure 25 information stored in memory to ascertain which DEM layer 23 should be accessed and where each such DEM layer 23 is located.

While it is of general use to have information stored information in a DEM data structure 21 related to both elevation and direction regardless of the manner in which such data is stored, the invention provides a manner in which to store elevation and direction data that reduces storage requirements, speeds up data processing, and increases the accuracy of stored DEM data. These attributes result from the manner in which the invention samples a DEM array 23′ to produce another DEM array of lesser resolution, the manner in which normal vectors are computed from each DEM data array 22 to populate each corresponding normal vector array 24, and the manner in which the normal vectors are stored in each normal vector array 24. The manner in which each of these is accomplished in the invention will now be discussed in detail.

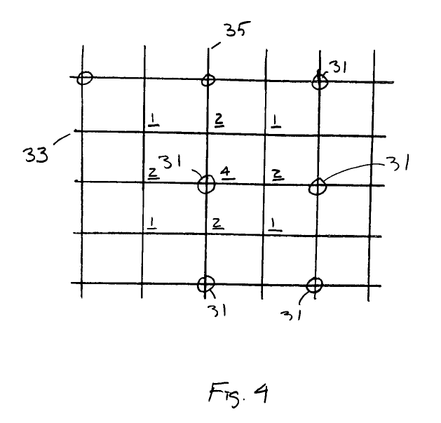

With reference to FIG. 4, there is illustrated a portion of a DEM comprised of horizontal rows, vertical columns, and nodes 31 located at the intersections of rows and columns. There is illustrated the method by which a DEM data array 22 is sampled with a sample rate of 2. This is indicated by the fact that only every other node 31 is highlighted (by a circle at each highlighted node 31. As such, each node 31 is being computed from the underlying DEM data which is comprised of horizontal and vertical lines which appear at twice the frequency of the nodes 31 in the x and y directions. In order to sample a DEM data array 22 in this manner, a sampled elevation value is computed for each node 31. This is accomplished by applying a mask to each node 31. In the exemplary embodiment shown, the mask in consists of nine mask values each value equaling either 1, 2, or 4. The mask values are illustrated as being underlined and surrounding exemplary node 31. Specifically, the mask is comprised of four values equaling one wherein each such value located both one column and one row away from the node 31 being computed, four values equaling two each such value located either one column or one row away from the node 31 being computed, and one value equaling 4 and located at the same point as the node 31 being computed.

Applying the mask to the node 31 to be computed is accomplished as follows. To compute a sample node 31, the surrounding eight elevation values as well as the original node value stored in the original DEM data array 22 is accessed one at a time. Each time an elevation value is accessed it is multiplied by the appropriate mask value. A sum is maintained of the products of each such multiplication. When all nine elevation values have been multiplied by the proper mask value and summed, the sum is divided by the sum of the mask values (in this example 1+1+1+1+2+2+2+2+4=16) to obtain the new sampled node 31 value. It is the value which is stored in the succeeding DEM array 23′. Often times, a DEM data array 22 contains missing values. If a data element of a DEM data array 22 contains a missing value, the data element is ignored and is not combined with a mask value. In such an instance, nothing is added to the running sum of products. In addition, when the sum is divided by the sum of the mask values, the sum of the mask values is computed to omit the mask values associated with missing values. In a similar manner, when computing nodes 31 which lie around the perimeter of the DEM data array 22, some mask values will be undefined. These undefined values are treated in the same manner as are missing values. For example, when computing the node 31 corresponding to the data element at DEM array [1][1], there are no values to the left or above the node 31. In this instance, the four values located directly to the right, directly below, diagonally to the right and below, and directly under the node 31 to be computed are multiplied by their corresponding mask values, summed, and the sum is divided by 9 (4+2+2+1=9) to achieve the final result.

The effect of computing a sampled elevation value in this manner is that that sampled value is an average of the original values which surround it and, as such, produces a smoother DEM data array 22 absent abrupt changes which might result in a less pleasing image when displayed. Note that the elevation values located furthest from the node 31 to be computed are given a mask value of one, the elevation values next closest to the node 31 to be computed are given a mask value of two, and the elevation value directly on top of which is located the node 31 to be computed is given a mask value of 4. In this manner, the average is weighted so that the sampled elevation value is more influenced by elevation values closest to it and less influenced by values located further away. Therefore, while illustrated with a mask comprised of values arrayed in a three-by-three matrix and with values of 1, 2, and 4, in practice the mask array size may be altered as well as the mask values employed to achieve a desired result.

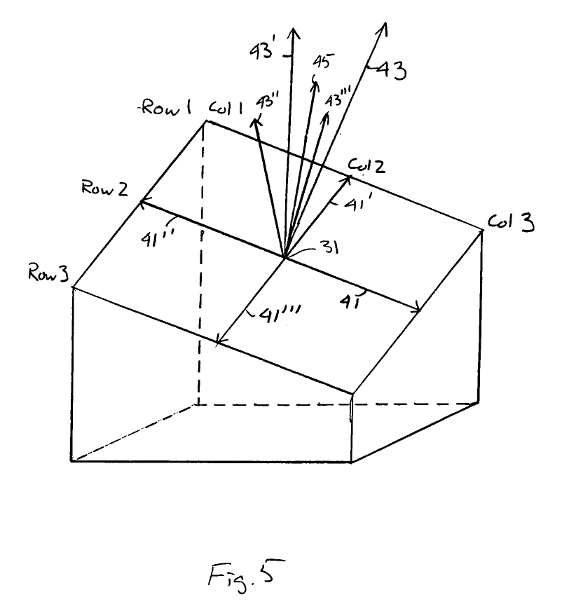

From each DEM data array 22, there is created a normal vector array 24. In an exemplary embodiment, each normal vector array 24 is comprised of an array of unsigned integers each unsigned integer being two bytes in length. As noted, each data element stored at a row and column of a normal vector array 24 contains the value of vector normal to the point on the surface of the corresponding DEM data array 22 at the same row and column. With reference to FIG. 5, there is illustrated a node 31 in a DEM grid 11 from which a normal vector is to be computed. There is further illustrated four vectors 41, 41′, 41″ and 41′″. These four vectors have as a common base point the node 31 itself. The four vectors have directions pointed directly to the right, directly up, directly to the left, and directly down and terminating upon the data element located directly to the right, directly up, directly to the left, and directly down from the node 31. The length of each vector is derived from the DEM data array 22 to be the actual distance between the data elements forming the base and the terminus of each vector once each data element is converted to the longitude and latitude and mapped to a sphere of known radius at the proper elevation. Next, the vectors 41, 41′, 41″, 41′″ are combined to form four cross products. Vector 41 is crossed with vector 41′ to produce cross product vector 43. Vector 41′ is crossed with vector 41″ to produce cross product vector 43′. Vector 41″ is crossed with vector 41′″ to produce cross product vector 43″. Lastly, vector 41′″ is crossed with vector 41 to produce cross product vector 43″″. The resulting four cross product vectors 43 are then averaged to create a normal vector 45 and the normal vector 45 is stored in normal vector array 24.

Note that the computation of each normal vector 45 is quite resource intensive in that it requires a large amount of computation to compute each normal vector 45. Because each normal vector array 24 corresponds to a DEM data array 22 which does not change over time, a normal vector array 24 which takes large amount of computations to create need be created and stored in the DEM structure 21 of the invention only once and may be quickly referenced as many times as is desired thereafter. To achieve this result, normal vector array 24 can take many forms. For example, normal vector array 24 can be comprised of three arrays each array holding one each the value of the x, y, and z component of the normal vector stored at a row and column. While the invention is not limited to the manner in which each normal vector array 24 stores the x, y, and z components of the normal vectors contained within each normal vector array 24, in one exemplary embodiment there is illustrated a manner by which a normal vector array 24 may be constructed to achieve economy of space and increased representational accuracy.

To achieve the aforementioned result, each normal vector is computed to be a unit vector with an associated scale factor and is stored as a single unsigned integer. Because one is primarily interested in the direction of a normal vector and not its magnitude, the magnitude information may be effectively discarded. This is accomplished when any vector is converted to a unit vector. All unit vectors are one unit in length so that the only information conveyed is that of direction. As a result, if one squares and sums the x, y, and z components of a unit vector, the result equals one. Specifically, x²+y²+z²=1 where x, y, and z are the vector's three orthogonal components. Therefore, if one knows any two values, one can compute the third. For example if one knows only the x and y components, one can compute the z component as equal to sqrt(1−x²−y²). As a result, normal vector array 24 need only store the x and y components of each normal unit vector and the z component can be derived when needed.

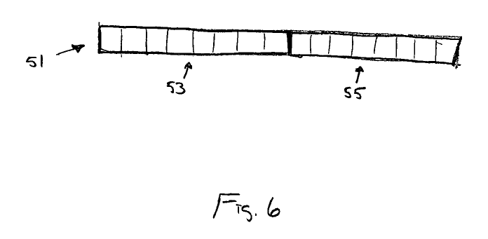

The question next arises of how to efficiently store the x and y components in a manner which affords sufficient accuracy while not unnecessarily increasing the size of the normal vector array 24. With reference to FIG. 6, there is illustrated an exemplary embodiment of a single data element 61 of a normal vector array 24. Unsigned integer 51 is comprised of two bytes represented by x byte 53 and y byte 55 corresponding to the normal vector's 45 x and y component respectively. However, while each component of each normal vector 45 is preferably computed as a floating point number to preserve the accuracy of each component which can vary between a value of zero and one, simply converting the components to integer values would, in effect, destroy the value of the component which would be forced to take a value of either zero or one. In the present invention, the x and y components are converted to integer values which preserve their accuracy as follows. Each x and y component is converted from a floating point number between −1 and 1 to a number between −125 and 125 equal to the floating point value multiplied by 125 and rounded to the nearest integer. When retrieved, the integer value may be divided by 125 and stored as a floating point number to reconstruct the original value of the x or y component of the vector. To assure that the integer values for both the x and y components are all positive, they are added to 128 and saved side by side. Specifically, the x component is stored in x byte 53 and the y component is stored as y byte 55 forming a single unsigned integer 51. Unsigned integer 51 therefore contains all of the information required to reconstruct the normal vector 45.

To reconstruct a single normal vector 45 from a single data element in a normal vector array 24 one proceeds as follows. First, retrieve the unsigned integer 51 stored as a data element at the row and column desired. Next, one separates the x and y components. This may be accomplished by setting a temporary x integer variable equal to unsigned integer 51 divided by 256. Register shifts can also be employed. In a similar manner, a temporary y integer variable is set equal to y byte 55. The temporary x and y variables can then be stored into temporary x and y floating point variables respectively and discarded. The temporary floating point values each then have 128 subtracted from them and the result is divided by 125. In this manner the temporary floating point x and y values now hold the original floating point x and y components between −1 and 1. As described above, once the x and y components of a normal vector are retrieved, one can calculate the z component of the normal vector.

While the aforementioned method allows one to store the x and y components of unit vectors in relatively compact format free of substantial data loss, it is possible to improve even more the resolution of the x and y vector components through the use of a scale factor. With the computation of successive DEM arrays 22 in successive DEM layers 23 according to the present invention, the resulting DEM arrays 22 become progressively smoother. As a result, the normal vectors 45 tend to point more and more in the z direction in successive DEM layers 23. When a vector points predominantly in the z direction, the vector's z component is relatively large while its x and y components are correspondingly smaller. While in the exemplary embodiment outlined herein each x and y component is defined by 125 gradations in the positive and negative direction, this resolution becomes less satisfactory as more and more DEM layers 23 are computed. In the first DEM layer 23 of the highest resolution, the normal vectors stored in normal vector array 24 are fairly uniformly distributed such that there are probably many x and y components of different data elements that approach +−125. However, as the DEM grid 11 is successively sampled to produce succeeding DEM layers 23, all of the x and y component values tend towards the center value of zero as the sampled DEM array represents more and more flat surfaces.

In recognition of this tendency for all of the normal vectors comprising a normal vector array 24 to point increasingly in the z direction as successive normal vector arrays 24 are computed, there is introduced a scale factor. Each time a single DEM data array 22 is processed to produce its corresponding normal vector array 24, the absolute value of the maximum x component value and y component value present in any data element of the normal vector array 24 is kept track of. After the x and y components have all been calculated as floating point numbers but before they are converted to integers and stored as unsigned integer 51 a scale factor is computed and utilized as follows. The larger of the absolute value of the maximum x component value and y component value is divided by 125 and stored as a scale factor. Next, the x and y component of every data element in the normal vector array 24 is recomputed to equal the previous value divided by the scale factor. In this manner, all of the x and y vector components in a single normal vector array 24 are scaled to fit between −125 and 125. From this point, each component has 128 added to it, is converted to an integer and stored as unsigned integer 51 as before. However, when converting from unsigned integer 51 to floating point values as before, each floating point variable holding either an x or a y component value is multiplied by the scale factor to retrieve the original floating point value of both and x and y component of the unit vector. Because each DEM layer 23 has a corresponding and unique scale factor, the scale factor for each DEM layer 23 is stored in each DEM layer's 23 corresponding DEM structure 25.

With reference to the scale factor, there are other advantageous methods by which it may be calculated. In the exemplary embodiment described above, the scale factor was computed to stretch the vector possessing the largest absolute value of the maximum x component value or y component value to a new value of +−125. However, it is possible that although most all of the normal vectors associated with DEM data array 22 are nearly vertical, there may be a single normal vector which lies predominantly in the x or y plane. In such an instance, the scale factor would have little effect of the accuracy with which the normal vectors are stored. When such is the case, it is sometimes preferable to histogram the absolute maximum x and y component values to a certain percentile, scale the vector falling at the histogram limit to +−125, and assign any vectors which scale to a value whose absolute value is greater than 125 either 125 or −125 as is appropriate.

With reference to FIG. 2, there is illustrated the inclusion of one or more percentile arrays 26. Each percentile array is associated with a single DEM layer 23 and includes statistical information describing the associated DEM layer 23. In the exemplary embodiment shown, each percentile array 26 is a one dimensional array of four hundred and one floating point elements. As a result, each element represents approximately one quarter of one percent. When the distance between the highest and the lowest elevation in a corresponding DEM layer 23 is computed, the distance is divided into four hundred bins and the number of data elements in DEM layer 23 falling into each bin is stored in a percentile array 26. By accessing a percentile array 26, one can efficiently histogram the distribution of elevations in a DEM layer 23, such as when displaying the data in a DEM data structure 21 color coded by elevation.

In summary, the invention teaches a DEM data structure 21 that provides the capability to store large amounts of high resolution elevation data while facilitating the rapid acquisition and display of the DEM data structure's 21 data or any subsection of the data regardless of the resolution at which it is displayed. This is accomplished by computing a plurality of DEM layer 23 at varying resolutions, storing the resulting DEM layers 23 in a DEM data structure 21, then accessing and utilizing the particular DEM layer 23 that is closest to the desired resolution. In a similar manner, normal vectors to each point in a DEM layer 23 are computed and statically stored for future reference. As a result, the normal vectors are computed once and need be only retrieved when needed. These normal vectors can be utilized, for example, to shade representations of the data contained in the DEM data structure 21, compute surface runoff and watersheds, and the like.

The foregoing description has provided by way of exemplary and non-limiting examples a full and informative description of the best method and apparatus presently contemplated by the inventors for carrying out the invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention.

What is claimed is:

1. A data structure stored on a computer readable storage media, comprising:
a plurality of layers each comprising a data array and a corresponding normal vector array; and
a plurality of layer structures each comprising information related to a corresponding one of said plurality of layers.

2. The data structure of claim 1 wherein each of said plurality of data arrays comprises a plurality of data elements each having a magnitude attribute.

3. The data structure of claim 2 wherein the magnitude attribute is an elevation.

4. The data structure of claim 2 further comprising a header structure comprising an information describing said data structure.

5. The data structure of claim 4 wherein said information comprises at least one of a latitude and a longitude of an area, a latitude and a longitude of an upper left most data element, a pointer to a first one of said plurality of layer structures, a number of said data elements per degree of longitude, a number of said data elements per degree of latitude, and a number of said plurality of layer structures in the data structure.

6. The data structure of claim 1 wherein at least one of said plurality of layer structures comprises a scaling factor.

7. The data structure of claim 1 wherein said plurality of normal vector arrays comprise a plurality of vector elements.

8. The data structure of claim 7 wherein each of said plurality of vector elements comprises a unit vector.

9. The data structure of claim 8 wherein each of said plurality of unit vectors is scaled by a scaling factor.

10. The data structure of claim 7 wherein each of said plurality of vector elements is an unsigned integer.

11. The data structure of claim 1 further comprising a plurality of percentile arrays each corresponding to one of said plurality of layers.

12. A signal bearing medium tangibly embodying a program of machine-readable instructions executable by a digital processing apparatus to perform operations comprising:
retrieving data from a data structure comprising:
a plurality of layers each comprising a data array and a corresponding normal vector array; and
a plurality of layer structures each comprising information related to a corresponding one of said plurality of layers; and
displaying the retrieved data.

13. The signal bearing medium of claim 12 wherein each of said plurality of data arrays comprises a plurality of data elements each having a magnitude attribute.

14. The signal bearing medium of claim 13 wherein the magnitude attribute is an elevation.

15. The signal bearing medium of claim 12 wherein said data structure additionally comprises a header structure comprising an information describing said data structure.

16. The signal bearing medium of claim 15 wherein said information comprises at least one of a latitude and a longitude of an area, a latitude and a longitude of an upper left most data element, a pointer to a first one of said plurality of layer structures, a number of said data elements per degree of longitude, a number of said data elements per degree of latitude, and a number of said plurality of layer structures in the data structure.
